(19) United States
(12) Patent Application Publication
(10) Pub. No.: US 2008/0242062 A1
(43) Pub. Date: Oct. 2, 2008

(54) FABRICATION OF DIVERSE STRUCTURES ON A COMMON SUBSTRATE THROUGH THE USE OF NON-SELECTIVE AREA GROWTH TECHNIQUES

(75) Inventors: Pietro BERNASCONI, EATONTOWN, NJ (US); Asish BHARDWAJ, EATONTOWN, NJ (US); David NEILSON, OLD BRIDGE, NJ (US); Liming ZHANG, MARLBORO, NJ (US)

Correspondence Address: BROSEMER, KOLEFAS & ASSOCIATES, LLC - (LUCENT), 1 BETHANY ROAD, BUILDING 4 - SUITE # 58, HAZLET, NJ, 07730, US

(73) Assignee: LUCENT TECHNOLOGIES INC., MURRAY HILL, NJ (US)

(21) Appl. No.: 11/694,978

(22) Filed: Mar. 31, 2007

(51) Int. Cl. H01L 21/20

(52) U.S. Cl. 438/494; 257/E21.09

(57) ABSTRACT

Diverse semiconductor structures are fabricated on a single substrate or wafer by using a non-selective area growth technique involving deposition of material over the entire substrate. The fabricated structures are obtained by selective removal of portions of the deposited material layers. Single level and multi-level structures are possible.

### TECHNICAL FIELD

This disclosure relates to semiconductor processing. More particularly, this disclosure relates to making diverse semiconductor material structures on a single substrate without using selective area growth techniques or conventional local butt-joint procedures.

### BACKGROUND

The performance of integrated semiconductor optoelectronic devices can be drastically improved if the different parts of the device itself are optimally supported by the appropriate diverse material structures. So, if more than one material structure is required for the implementation of the device, these have to be conveniently fabricated on a common substrate. For example, indium phosphide-based optical optoelectronic devices require excellent properties for passive optical guiding structures as well as excellent performance of optically active sections. In the case of passive optical guiding structures, propagation losses may be a parameter to be optimized. For optically active sections, optical gain or non-linear response may be the parameters to optimize. It is hard to find a common material structure that can simultaneously optimize those different individual functionalities in a single structure. Accordingly, multiple separate structures, each having a desired individual characteristic, have to be grown on a single substrate to accommodate the requirements of the individual parts of the optoelectronic device.

In the past, this has been accomplished for example through so-called butt-joint growth techniques and selective area growth (SAG) techniques, i.e. processes which selectively grow material structures in predefined limited areas on a wafer or generate variations of a material structure during a single deposition step. These techniques, however, suffer from negative side-effects and limitations in the variety of structures they can provide and often limit the size of the area on which they can be applied, as well. This is related to the methods used for material growth that rely typically on metal-organic chemical vapor deposition (MOCVD) or metal-organic vapor pressure epitaxy (MOVPE) or other epitaxial techniques.

For example, localized butt-joint growth techniques allow for each growth step the deposition of a substantially different material structure optimized for a specific task, e.g. low-loss passive optical guides, highly linear optical amplification, or strongly nonlinear optical effects, etc. Practically, this is achieved as for example shown in FIG. 5. A first layer (20) is deposited on a substrate and patterned with a mask (22) that defines where part of layer (20) will be removed (FIG. 5d) and replaced with another material structure. The mask (22) is thus used first during the etching step that creates the gap and, second, to inhibit the regrowth of the new material (44, 46) outside the desired areas. Note that different masks, but with essentially the same topology, may be used during the etching and the growth steps. Although this method can potentially grow very different types of materials (46) from those already deposited (20), it typically produces non-homogeneous growth effects in the vicinity of the mask's edges. These are caused by different thermodynamic conditions in the vicinity of the mask's edges that modify the accumulation process of the deposited chemical elements. These effects usually translate into variation of thickness, composition, and internal strain of the deposited material that in turn generates discontinuities at the material interfaces that may be very detrimental to the final device.

A second method usually referred as selective area growth (SAG) is also known to provide local variations of a material structure during a single deposition step. This is achieved by taking advantage of the local effects described above to generate adjacent regions made out of the same kind of material but with different opto-electronic properties. These variations are induced by the presence of a mask that perturbs the deposition process. This produces local variations of thickness, composition, and strain of the grown compound. The success of this approach relies upon the precise layout and dimensioning of the mask as well as the precise control of the growth conditions. However, because this technique is based upon local or proximity effects, it poses limits on the sizes of the differently grown areas. In addition, the amplitude of the induced variations is also limited. From a material perspective, during SAG only the stoichiometric relation among the different chemical elements is modified, which in the example of a ternary or quaternary compound, may slightly change the material band gap. So quantum well-based structures (known to provide excellent active sections) and bulk materials (known for the good passive characteristics) cannot be produced at once with SAG. From a structural perspective, SAG can vary the layer thicknesses in different areas by taking advantage of its well-known enhancement growth factor. In case of QW structures, the variation of the thickness of both wells and barriers can lead to an appreciable change of the structure band gap. Although this variation may not be as large as those achievable via butt-joint growth, optically active and passive guiding structures can be simultaneously grown. Again the amplitude of the variations obtainable via SAG are limited by the size of the area in which the enhancement effects are expected. Moreover, the change in the layer thicknesses is often coupled to a change of the material intrinsic strain, which also limits the amplitude of the desired variations before catastrophic structural breakdown. Unlike local butt-joint growth processes, SAG can generate relatively smooth transition zones between two adjacent areas with different characteristics. Among the most difficult challenges are those related to the control of the exact material composition to be deposited, its exact thickness, and its homogeneity. In order to reduce the impact of such effects, SAG techniques often rely upon complicated photolithographic mask design that presumes an excellent control over the material deposition process, thus increasing the overall process complexity.

### SUMMARY

The proposed invention describes a method to providing a large variety of material structures with large differences in their opto-electronic properties on a single substrate that does not suffer from the limitations currently affecting both SAG and local butt-joint growth approaches. The invention may be used both in alternative to or in conjunction with the other two methods.

Multiple different material structures are built on a common substrate without resorting to techniques like selective area growth or local butt-joint growth. The approach allows reversing the step sequence of commonly used techniques, which leads to a simplified fabrication process and higher degree of structure optimization. The method is based upon consecutive steps of area insensitive material growth followed by area-sensitive material removal. No selective area growth or local butt-joint growth, i.e. growth of material structures only in limited designated areas, is required. Material growth occurs over the entire wafer surface improving the homogeneity of the deposited structures and therefore improving their quality. Besides being a simple and more tolerant material fabrication procedure, the approach simplifies the design and optimizes the use of masks necessary for the material removal steps without being subject to the size limitations imposed by SAG.

### BRIEF DESCRIPTION OF THE DRAWINGS

FIG. 1 is top view of a wafer made by an illustrative method in accordance with this invention.

FIG. 2 is a cross section of the wafer shown in FIG. 1 taken along line 2-2 in FIG. 1.

FIG. 3(a) to 3(n) illustrate an example of the method of semiconductor processing that may be used to make the structure shown in FIGS. 1 and 2.

FIGS. 4(a) to 4(n) illustrate another example of a method of semiconductor processing in accordance with the invention.

FIGS. 5(a) to 5(f) illustrate one of the problems with prior selective area growth techniques.

### DETAILED DESCRIPTION

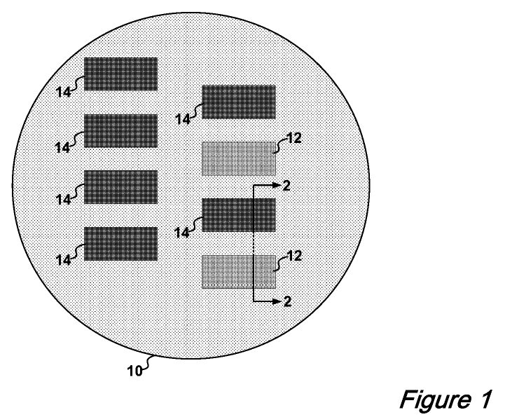

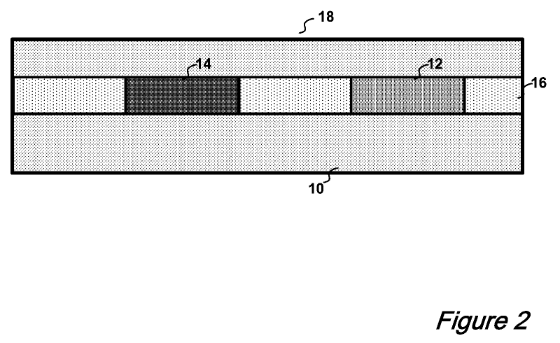

Advanced opto-electronic devices comprise parts that may require different material structures for optimal performance. For example, an integrated fast-tunable wavelength converter may need good optically active regions for optical gain (inside a laser cavity or for optical amplification), active regions to provide optical non-linearities, and regions supporting low-loss passive interconnects and other subcomponents such as filters, couplers, etc. A common problem is how to generate these distinct material structures on a single substrate as shown in FIGS. 1 and 2.

FIGS. 1 and 2 show a wafer 10 supporting one type of structure 12 formed in a layer 16 and a second type of structure 14 also supported in the layer 16. The layer 16 and the structures 12 and 14 may be covered by another layer 18. Layers 12 and 14 have differing chemical and/or physical properties that optimize their performance of particular tasks in the finished semiconductor device. For example, the structure 12 may be configured to provide an active region that optimizes optical gain; structure 14 may be configured to provide a different optimized characteristic such as large optical non-linearities. These different areas may be eventually interconnected by passive guides lying in the material structure 16 optimized e.g. for low propagation losses. Structure 12 illustratively may made of a quaternary material such as InGaAsP with band gap ˜1.6 microns. This structure would be absorptive at 1.5 microns, but would become an amplifier when pumped with current. Alternatively, structure 12 may also be a Multiple Quantum Well (MQW) structure which acts similarly to the quaternary material. There are differences in terms of efficiency, maximum gain, dynamic response, etc, so one is used instead of the other depending upon which parameter one would like to optimize. Structure 14 may be an MQW or another quaternary material with a different band gap. Structures 12 and 14 may also be two different types of MQWs with different characteristics (efficiency, maximum gain, dynamic response, etc). In addition to quaternary compounds and MQWs for structures 12 and 14, there are also many other options such as binary (e.g. InP, GaAs) and ternary compounds based upon combinations of In, P, Ga, As, Al, and others. Like structures 12 and 14, structure 16 may be made out of quaternary or MQW materials with a smaller band gap in order to provide low-loss guiding characteristics. All these layers can be grown through various epitaxial techniques.

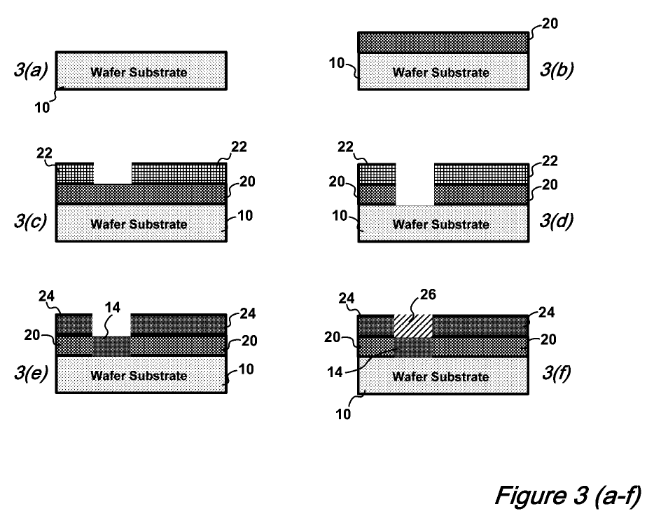

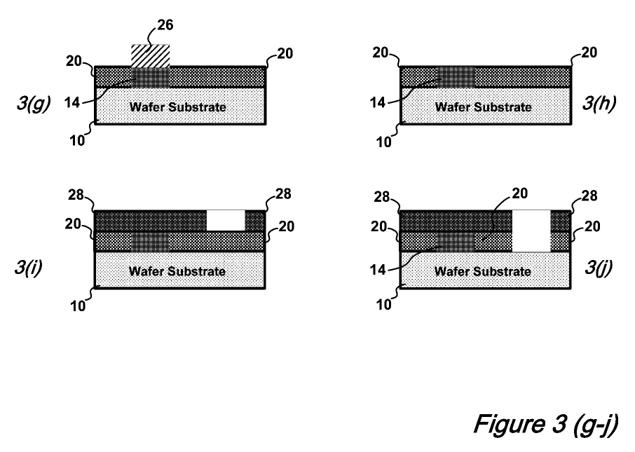

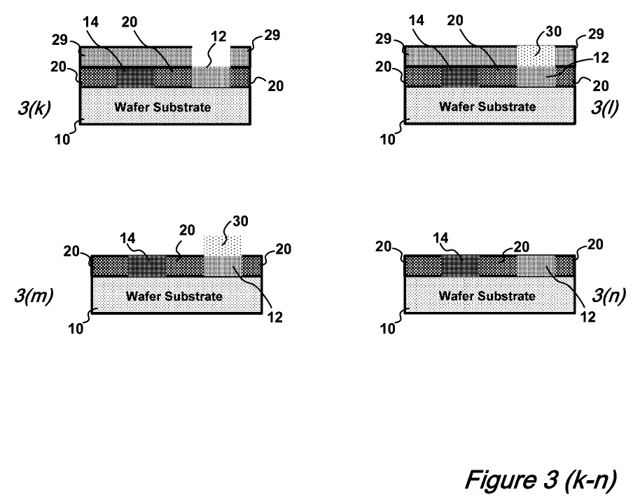

The procedure of making a device like to one shown in FIGS. 1 and 2 comprises consecutive steps of non-selective material growth and selective material removal, for example, etching, as illustrated in FIGS. 3(a) to 3(n). Note that etching steps can be controlled with excellent accuracy. Starting with a base wafer or substrate 10 in FIG. 3(a), made, for example, of undoped InP, a first material structure 20 is homogeneously grown over the entire surface as shown in FIG. 3(b). The structure 20 may be made of a quaternary compound InGaAsP and is for the purpose of providing a low-loss passive optical guiding layer. In this regard, layer 20 can have for example a band gap ˜1.3 microns, which will make it transparent at an optical wavelength of 1.5 micron and thus will make it useful as a passive optical waveguide. A mask 22 then is deposited and patterned on the structure 20 as shown in FIG. 3(c) to allow for selective etching of the underlying layer 20, as shown in FIG. 3(d). This etching process can be limited to very shallow depths, which improves the controllability and reproducibility of the process. The etching may just partially remove the material of layer 20, remove it completely down to the substrate 10, or even penetrate into the substrate itself. After the removal of the mask 22, a second material structure 24 is grown on the entire wafer's surface, as shown in FIG. 3(e). As shown in FIG. 3(e), part of the material structure 24 is the structure 14 in FIGS. 1 and 2. In FIG. 3(f), a mask 26 complementary to mask 22 is deposited as in FIG. 3(c) before the excess of layer 24 is etched away in FIG. 3(g). Once the protecting mask 26 is removed in FIG. 3(h), the same sequence of FIGS. 3(c) to 3(h) can be repeated in FIGS. 3(i) to 3(n) with different masks 28 and 30. A second material structure 32 is deposited over the entire wafer 10; material structure 32 contains structure 12 shown in FIGS. 1 and 2. Although the fabrication of two structures 12 and 14 is accomplished by the processing shown in FIGS. 3(a) to 3(n), the processing could be repeated any number of times to produce a third structure and possibly more structures on the wafer depending on the needs of the semiconductor device being fabricated.

The mask layer 22 formed in FIG. 3(c) and mask layer 26 formed in FIG. 3(f) can be generated using the same photolithographic plate for example by simply replacing a positive photoresist with a negative one, or vice versa. Similarly, the mask layer 28 formed in FIG. 3(i) and the mask layer 30 formed in FIG. 3(1) can be produced by the same photolithographic plate. This implies an easier design effort and a reduced cost in terms of the number of photolithographic plates needed.

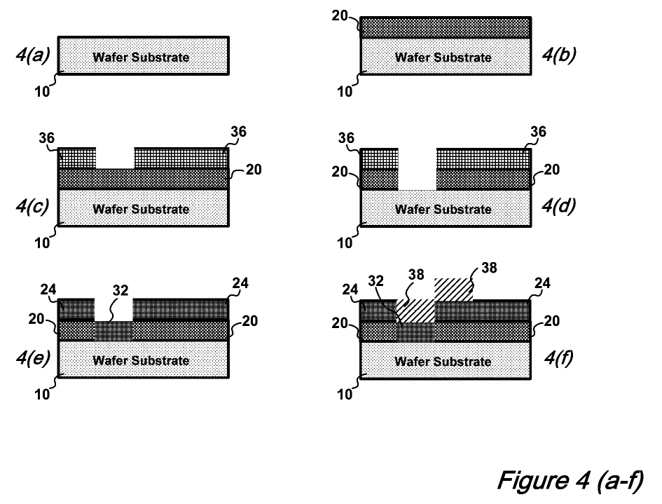

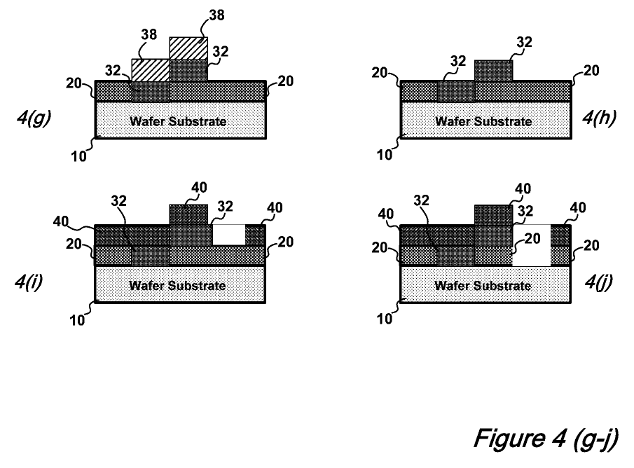

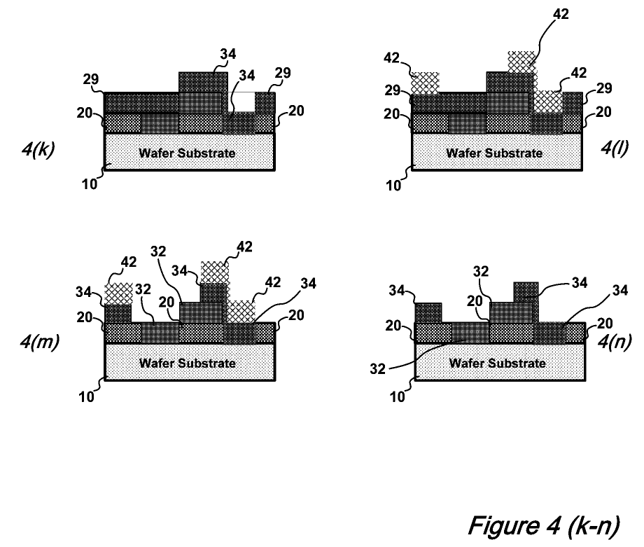

The approach shown in FIGS. 3(a) to 3(n) can also be easily modified to create more complex material structures 32 and 34 as shown in FIGS. 4(a) to 4(n). In this second case, the mask layer 36 deposited in the step shown in FIG. 4(c) and the mask layer 38 deposited in the step shown in FIG. 4(f) are not complementary replicas of one another. Similarly, mask layer 40 deposited in the step shown in FIG. 4(i) is not the complement of the mask layer 42 deposited in the step shown in FIG. 4(l). This allows for the generation of more complex multi-layer and overlapping structures, such as structures 32 and 34. In all other respects the process depicted in FIGS. 4(a) to 4(n) is the same as the process of FIGS. 3(a) to 3(n), respectively.

A major advantage of the approach described here is that all material layers are always deposited over the entire wafer surface. This provides a high quality deposition of the material with a much better homogeneity, which will eventually translate into better performance in the final devices. The deposition process is also simplified—a new material structure always relies upon the same sequence of etch followed by a homogeneous growth, and in the case depicted in FIG. 3(a) to 3(n), the same photolithographic mask can be used throughout the whole cycle. Besides the cost advantages of a reduced set of photolithographic plates, the higher material quality will also increase the yield obtained from a finished wafer, thus reducing the cost per device.

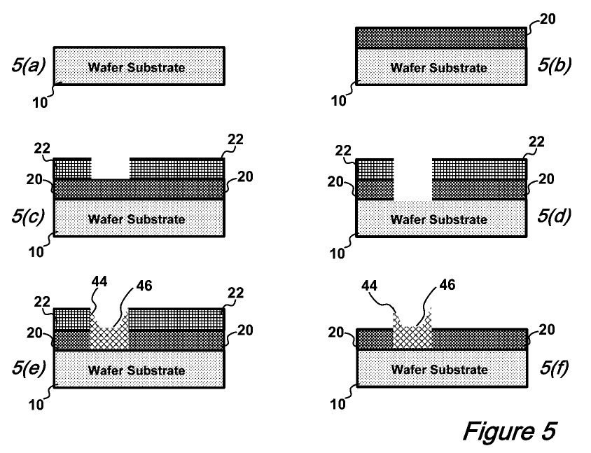

Compared to other procedures, this approach offers several additional advantages. For example, compared to the conventional butt-joint growth, this approach is not affected by local effects that may compromise the interface between different material structures. Such effects of enhanced growth are strongly dependent upon the topology of the mask and particularly difficult to control as schematically shown by the regions 44 of enhanced growth in grown structure 46 in the deposition process depicted in FIGS. 5(a) to 5(f). They may eventually be the sources of problems at the interfaces between different material structures and negatively affect the performance of the final devices. Because the material is deposited over the entire wafer, it is easier to control its thickness and homogeneity. So there is virtually no restriction on the size of the grown material structure and many areas with a wide variety of sizes can be processed at once.

This may not be the case when SAG is used since the final thickness, composition and/or strain of the deposited material strongly depends upon the size and relative position of the grown areas. Therefore it may not be possible to grow the same material structure on areas of different size so that multiple deposition steps may be necessary to achieve this goal. This would increase the complexity and eventually the cost of the devices. In addition, the current invention makes available a larger variation in the material parameters and structures than what can be achieved by a single step of SAG.

The present invention also offers another advantage with respect to the other techniques because it does not use any mask during the growth process. In both the local butt-joint growth and SAG, masks (typically consisting of dielectric materials) are needed to confine or perturb the deposition process. It may happen that during the deposition some material may adhere to the mask and may eventually prevent a complete and clean removal of the mask itself. In that case, the spot occupied by this residual material may not be used for other purposes effectively reducing the surface available for the integration of opto-electronic components.

The approach described here is not subject to enhanced growth effects that may appreciably change the growth rate and thus the final thickness of the deposited material. With local butt-joint techniques, enhanced growth effects are commonly observable along the edges of the grown material. In fact, in order to deposit the desired material on a limited area, the rest of the surface is protected by a mask that prevents or inhibits the material growth. So the material present on the mask tends to diffuse and accumulate at the edges of the mask itself eventually increasing the thickness of the deposited structures at the interfaces. Such effects of enhanced growth are strongly dependent upon the topology of the mask and particularly difficult to control as schematically shown by the regions 44 of enhanced growth in grown structure 46 in the deposition process depicted in FIGS. 5(a) to 5(f). They may eventually be the sources of problems at the interfaces between different material structures and negatively affect the performance of the final devices.

The solution described here greatly simplifies the fabrication of opto-electronic devices requiring several different types of material structures on a single wafer. The flexibility offered by this method will also support the fabrication of new and more powerful devices with a wider range of functionality. It will also provide new powerful tools to support the path towards higher degree of integration in the opto-electronic field.

The Title, Technical Field, Background, Summary, Brief Description of the Drawings, Detailed Description, and Abstract are meant to illustrate the preferred embodiments of the invention and are not in any way intended to limit the scope of the invention. The scope of the invention is solely defined and limited by the claims set forth below.

1. A method of fabricating first and second diverse structures on a substrate, comprising the steps of:
(a) forming a first layer of material over the entire surface of a substrate;
(b) applying a first mask to a selected portion of the first layer;
(c) removing an unmasked portion of the first layer from the wafer;
(d) removing the first mask from the substrate;
(e) forming a second layer of material over the entire surface of the substrate;
(f) applying a second mask to the second layer of material;
(g) removing an unmasked portion of the second layer of material from the substrate and leaving a masked portion of the second layer on the substrate;
(h) removing the second mask from the substrate, thereby leaving the first structure on the substrate defined by the portion of the second layer remaining on the substrate; and
(i) repeating steps (b) through (g) above to form the second structure on the substrate.

2. The method of claim 1, in which the second mask is complementary to the first mask.

3. The method of claim 1, in which the first and second structures are in a single level on the substrate.

4. The method of claim 1, in which the first and second structures are in multiple levels on the substrate.

5. A method of fabricating first and second diverse structures on a substrate having a material growth surface, comprising the steps of:
non-selectively growing a first layer of material over substantially the entire growth surface of the substrate;
removing a portion of the first layer of material from the substrate leaving the first structure on the substrate;
non-selectively growing a second layer of material over substantially the entire growth surface of the substrate; and
removing a portion of the second layer of material from the substrate leaving the second structure on the substrate.

6. The method of claim 5, in which the first structure is optimized for a first property and the second structure is optimized for a second property.

7. The method of claim 5, in which the first structure has a first chemical composition stoichiometry and the second structure has a second chemical composition or stoichiometry.

8. The method of claim 7, in which at least one of the first and second chemical compositions comprises semiconductor materials.

9. The method of claim 7, in which the at least one of the first and second chemical compositions comprises III-V chemical compounds.

10. The method of claim 7, in which the at least one of the first and second chemical compositions comprises an indium phosphide-based composition.

11. The method of claim 1, in which no mask is used during the forming steps so that the layers of material are deposited over substantially the entire surface of the substrate.

12. The method of claim 1, in which no dielectric mask is used during the forming steps so that the layers of material are deposited over substantially the entire surface of the substrate.

13. The method of claim 5, in which no mask is used during the growing steps so that the layers of material are deposited over substantially the entire surface of the substrate.

14. The method of claim 5, in which no dielectric mask is used during the growing steps so that the layers of material are deposited over substantially the entire surface of the substrate.
